(19) United States
(12) Patent Application Publication
(10) Pub. No.: US 2026/0164631 A1
(43) Pub. Date: Jun. 11, 2026

(54) VOLTAGE DISTRIBUTION NETWORK FOR MEMORY ARRAY

(71) Applicant: Taiwan Semiconductor Manufacturing Company, Ltd., Hsinchu (TW)

(72) Inventors: Yi-Hsin Nien, Hsinchu (TW); Chih-Yu Lin, Taichung City (TW); Hidehiro Fujiwara, Hsinchu (TW); YEN-HUEI CHEN, Hsinchu (TW)

(21) Appl. No.: 18/971,894

(22) Filed: Dec. 6, 2024

(51) Int. Cl. H10B 10/00

(52) U.S. Cl. CPC H10B 10/12

(57) ABSTRACT

A memory device includes a memory array having a plurality of memory cells and a core voltage distribution network connected to the plurality of memory cells. Each of the plurality of memory cells includes a conductive layer over an active area and a first conductive layer connected by a first via to the conductive layer over the active area. The core voltage distribution network includes a second conductive layer that includes a second conductive layer island connected by a second via to the first conductive layer and a third conductive layer connected by a third via to the second conductive layer island.

### BACKGROUND

Typically, a memory device includes an array of memory cells, such as an array of static random-access memory (SRAM) cells. The memory device includes a primary power supply voltage, such as a voltage drain-to-drain (VDD) or a voltage collector-to-collector (VCC) power supply voltage, that supplies power to core circuitry, such as the memory array, and to input/output (IO) circuitry of the memory device. The primary power supply voltage supplies a core power supply voltage, such as a core voltage drain-to-drain (CVDD) power supply voltage, that supplies power to the core circuitry of the memory device including the memory array.

To increase the density of memory cells in a memory array, manufacturers try to increase the number of word lines (WLs) in the memory array. However, increasing the number of WLs in the memory array, increases voltage drops on the CVDD power supply lines, which lowers the maximum voltage Vmax that reaches the memory cells and degrades the read static noise margin (RSNM) of the memory cells.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the disclosure and are not intended to be limiting.

FIG. 1 is a diagram schematically illustrating a memory device that includes a memory array including a plurality of memory cells connected to a core voltage distribution network, such as a CVDD power mesh, in accordance with some embodiments.

FIG. 2 is a diagram schematically illustrating an SRAM cell used in the memory device of FIG. 1, in accordance with some embodiments.

FIG. 3 is a diagram schematically illustrating a layout of the SRAM cell of FIG. 2, in accordance with some embodiments.

FIG. 4 is a diagram schematically illustrating another part of the layout of the SRAM cell of FIG. 2, which includes a second conductive layer island connected to the CVDD power supply line in the first conductive layer, in accordance with some embodiments.

FIG. 5 is a diagram schematically illustrating another part of the layout of the SRAM cell of FIG. 2, which includes the second conductive layer island connected to a CVDD power supply line in a third conductive layer, in accordance with some embodiments.

FIG. 6 is a diagram schematically illustrating a memory array that includes power supply voltage islands in a second conductive layer, once every 4 rows, in each column of the memory array, in accordance with some embodiments.

FIG. 7 is a diagram schematically illustrating a memory array that includes a plurality of memory cells and power supply voltage lines that cross the memory array, including between the memory cells, in accordance with some embodiments.

FIG. 8 is a diagram schematically illustrating a method of manufacturing a memory device, in accordance with some embodiments.

FIG. 9 is a block diagram schematically illustrating an example of a computer system configured to provide the devices, including electronic devices and semiconductor devices, and methods of the current disclosure, in accordance with some embodiments.

FIG. 10 is a block diagram of a semiconductor device manufacturing system and a semiconductor device manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, in circuit designs, a power mesh refers to a network of power supply lines and reference lines placed across an integrated circuit (IC) or printed circuit board (PCB). The power mesh ensures a stable and efficient distribution of power to various components and subsystems within the circuit. The power mesh is designed to minimize voltage droops, reduce noise, and maintain a consistent power delivery across the circuit.

In SRAM memory devices, the CVDD power supply voltage is supplied by power supply voltage lines situated at a top edge of the memory array and at a bottom edge of the memory array. These power supply voltage lines are formed in a second conductive layer, such as a metal 1 (M1) layer, and connected to power supply voltage lines formed in a first conductive layer, such as a metal 0 (M0) layer. The power supply voltage lines in the first conductive layer cross the memory array and are connected to each of the memory cells in the memory array. In contrast to this, the reference voltage lines are formed into a reference mesh in a third conductive layer, such as a metal 2 (M2) layer, that crosses the memory array and is connected to each of the memory cells through vias and the first and second conductive layers. Thus, when increasing the number of WLs to increase the density of the memory cells in the memory array, the current-resistance (IR) voltage drops in the first conductive layer power supply voltage lines reduce the maximum voltage Vmax at the memory cells and degrade the RSNM of the memory cells, while the reference mesh contributes little to this reduction of the maximum voltage Vmax and degradation of the RSNM of the memory cells.

Disclosed embodiments provide a memory device that includes a CVDD power mesh that includes a second conductive layer, such as an M1 layer, that has a second conductive layer island connected by a via to a first conductive layer, such as an M0 layer, that is connected to memory cells in the memory device. A third conductive layer, such as an M2 layer, is connected by another via to the second conductive layer island to form the CVDD power mesh that increases the maximum voltage Vmax at the memory cells and improves the RSNM of the memory cells.

In some embodiments, each of the memory cells includes a second conductive layer island connected by a via to the first conductive layer, and a third conductive layer connected by another via to the second conductive layer island. In some embodiments, the memory device includes a memory array that includes the memory cells in rows and columns and each column of memory cells includes a memory cell once every 2 times N rows, where N is a positive integer, where the memory cell includes a second conductive layer island connected by a via to the first conductive layer, and a third conductive layer connected by another via to the second conductive layer island. In some embodiments, the memory array includes word lines in the second conductive layer, such that increasing N decreases the number of second conductive layer islands, which increases the power distribution network resistance and increases the word line area that reduces word line resistance and capacitance.

Disclosed embodiments further include a memory device that includes a memory array and a core voltage distribution network. The memory array includes a plurality of memory cells situated in rows and columns, where each of the plurality of memory cells includes a conductive layer over an active area and a first conductive layer connected by a via to the conductive layer. The core voltage distribution network includes a second conductive layer that includes at least one core voltage distribution line situated between rows of memory cells in the memory array and connected by at least one via to the first conductive layer. In some embodiments, the at least one core voltage distribution line includes core voltage distribution lines at a top of the memory array, a bottom of the memory array, and between the top and the bottom of the memory array, each connected by the at least one via to the first conductive layer. This core voltage distribution network increases the maximum voltage Vmax at the memory cells and improves the RSNM of the memory cells.

Disclosed embodiments further include a method of manufacturing a memory device. The method includes forming a plurality of memory cells in a memory array and forming a core voltage distribution network connected to the plurality of memory cells. Forming each of the plurality of memory cells includes forming a conductive layer over an active area, forming a first via over the conductive layer, and forming a first conductive layer over the conductive layer and connected to the conductive layer by the first via. Forming the core voltage distribution network includes forming a second via over the first conductive layer, forming a second conductive layer island over the first conductive layer and connected to the first conductive layer by the second via, forming a third via over the second conductive layer island, and forming a third conductive layer over the second conductive layer and connected to the second conductive layer island by the third via.

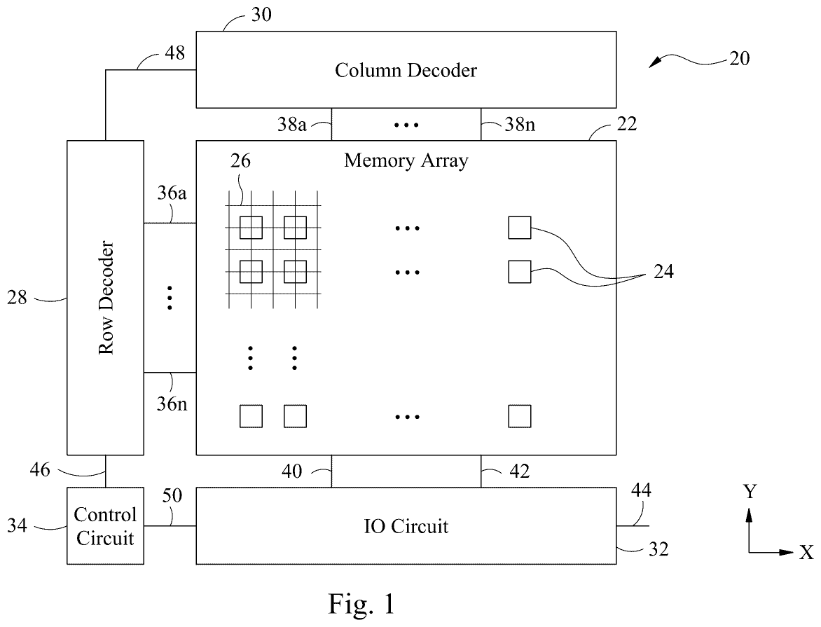

FIG. 1 is a diagram schematically illustrating a memory device 20 that includes a memory array 22 including a plurality of memory cells 24 connected to a core voltage distribution network 26, such as a CVDD power mesh, in accordance with some embodiments. The plurality of memory cells 24 are arranged in rows and columns in an x-y grid. In some embodiments, the plurality of memory cells 24 are SRAM cells. In some embodiments, the memory device 20 is an electronic device, one or more semiconductor devices, and/or one or more integrated circuit devices.

The memory device 20 includes the memory array 22, a row decoder circuit 28, a column decoder circuit 30, an IO circuit 32, and a control circuit 34. The row decoder circuit 28 is electrically connected to the memory array 22 by row lines 36a-36n that extend in the x-direction. The column decoder circuit 30 is electrically connected to the memory array 22 by column lines 38a-38n that extend in the y-direction. The rows extend along the x-axis and the columns extend along the y-axis of the x-y grid of the memory array 22.

The IO circuit 32 is electrically connected to the memory array 22 by conductive paths 40 and 42. The IO circuit 32 includes input circuits, output circuits, and sensing circuits for storing data in the memory cells 24 and sensing data from the memory cells 24. The IO circuit receives input data and outputs output data through IO path 44.

The control circuit 34 is electrically connected to the row decoder circuit 28 and the column decoder circuit 30 by conductive paths 46 and 48, and to the IO circuit 32 by conductive path 50. The row decoder circuit 28 receives and decodes row addresses and the column decoder circuit 30 receives and decodes column addresses. Also, the control circuit 34 provides instructions to the row decoder circuit 28, the column decoder circuit 30, and the IO circuit 32 to control operation of the memory device 20.

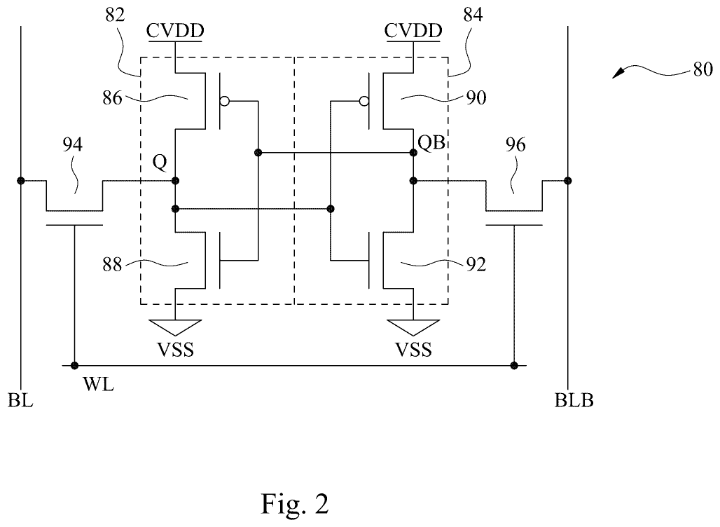

FIG. 2 is a diagram schematically illustrating an SRAM cell 80 used in the memory device of FIG. 1, in accordance with some embodiments. The SRAM cell 80 is a six-transistor (6T) SRAM cell. In some embodiments, the SRAM cell 80 is in the memory device 20 of FIG. 1. In some embodiments, the SRAM cell 80 is in the memory array 22 shown in FIG. 1. In some embodiments, the SRAM cell 80 is like the memory cells 24 in FIG. 1. In other embodiments, the SRAM cell 80 includes more or fewer than six transistors, such as four, eight, or ten transistors.

The SRAM cell 80 includes two cross-coupled inverters 82 and 84. The first inverter 82 includes a first PMOS/NMOS transistor pair 86 and 88, and the second inverter 84 includes a second PMOS/NMOS transistor pair 90 and 92. The SRAM cell 80 further includes a left pass gate transistor 94 and a right pass gate transistor 96.

Power is supplied to each of the inverters 82 and 84, where a first terminal of each of a left pull-up transistor 86 and a right pull-up transistor 90 is electrically coupled to a core voltage power supply CVDD, and a first terminal of each of a left pull-down transistor 88 and a right pull-down transistor 92 is electrically coupled to a reference voltage VSS, such as ground. A bit of data is stored in the SRAM cell 80 as a voltage at node Q and can be read through the left pass gate transistor 94 via the bit line BL, where access to the node Q is controlled by the left pass gate transistor 94. The node Q bar (QB) stores the complement of the value at node Q, such that if Q is high then QB is low and vice-versa. The node QB can be read through the right pass gate transistor 96 via the bit line bar BLB, where access to the node QB is controlled by the right pass gate transistor 96.

A gate of the left pass gate transistor 94 is coupled to a word line WL. A first source/drain (S/D) terminal of the left pass gate transistor 94 is coupled to the bit line BL, and a second S/D terminal of the left pass gate transistor 94 is coupled to the second terminals of the left pull-up transistor 86 and the left pull-down transistor 88 at the node Q and to the gates of the right pull-up transistor 90 and the right pull-down transistor 92.

Also, a gate of the right pass gate transistor 96 is coupled to the word line WL. A first S/D terminal of the right pass gate transistor 96 is coupled to the bit line bar BLB, and a second S/D terminal of the right pass gate transistor 96 is coupled to second terminals of right pull-up transistor 90 and right pull-down transistor 92 at the node QB and to the gates of the left pull-up transistor 86 and the left pull-down transistor 88.

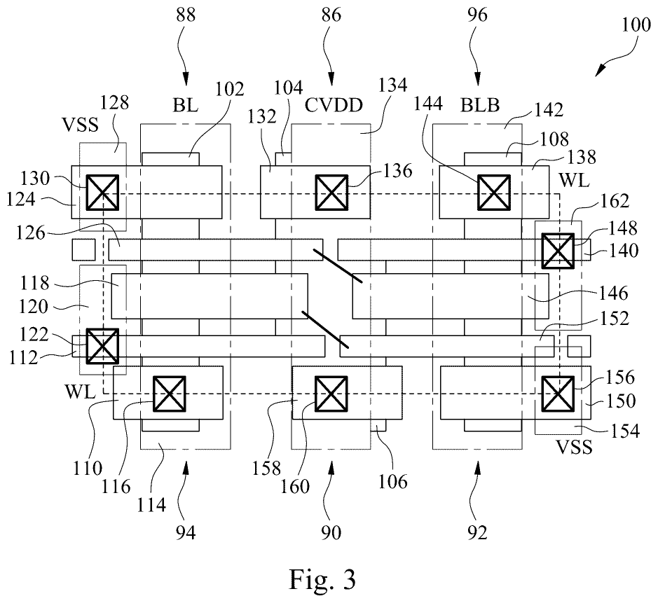

FIG. 3 is a diagram schematically illustrating a layout 100 of the 6T SRAM cell 80 of FIG. 2, in accordance with some embodiments. The layout 100 includes layers up to a first conductive layer that is a first metal layer M0.

The layout 100 includes the transistors 86, 88, 90, 92, 94, and 96 of the SRAM cell 80. The layout 100 includes active areas 102, 104, 106, and 108. The left pass gate transistor 94 is laid out with a conductive layer 110, such as a metal over diffusion (MD) layer, disposed on the first active area 102 on one side of a gate 112 of the left pass gate transistor 94. A bit line BL 114 in the first conductive layer contacts the conductive layer 110 through a first via 116, such that the bit line BL 114 is connected to the first active area 102 through the first via 116 and the conductive layer 110. Another conductive layer 118, such as a metal over diffusion (MD) layer, is disposed on the first active area 102 and on the second active area 104 on the other side of the gate 112 of the left pass gate transistor 94. The gate 112 of the left pass gate transistor 94 is connected to a word line (WL) 120 in the first conductive layer through a second via 122. In some embodiments, one or more dielectric layers (not shown for clarity) are disposed on the conductive layers, such as the conductive layers 110 and 118, and on the gate, such as the gate 112. The vias, such as the first via 116 and the second via 122, are formed through the dielectric layers. The first conductive layers, such as BL 114 and WL 120, are formed on the one or more dielectric layers, such that the conductive layers are electrically connected to the first conductive layers through the vias.

The left pull-down transistor 88 is laid out with a conductive layer 124, such as a metal over diffusion (MD) layer, disposed on the first active area 102 on one side of a gate 126, and a reference line 128 in the first conductive layer is connected to the conductive layer 124 through a third via 130. The other side of the gate 126 includes the conductive layer 118 disposed on the first active area 102 and on the second active area 104. The left pull-up transistor 86 is laid out with a conductive layer 132, such as a metal over diffusion (MD) layer, disposed on the second active area 104 on one side of the gate 126, and a CVDD power supply line 134 in the first conductive layer is connected to the conductive layer 132 through a fourth via 136. The other side of the gate 126 includes the conductive layer 118 disposed on the first active area 102 and on the second active area 104. The gate 126 of the left pull-down transistor 88 and the left pull-up transistor 86 crosses the first active area 102 and the second active area 104. In some embodiments, one or more dielectric layers (not shown for clarity) are disposed on the conductive layers, such as the conductive layers 124 and 132, and on the gate, such as the gate 126. The vias, such as the third via 130 and the fourth via 136, are formed through the dielectric layers. The first conductive layers, such as the reference line 128 and the CVDD power supply line 134, are formed on the one or more dielectric layers, such that the conductive layers are electrically connected to the first conductive layers through the vias.

The right pass gate transistor 96 is laid out with a conductive layer 138, such as a metal over diffusion (MD) layer, disposed on the fourth active area 108 on one side of a gate 140 of the right pass gate transistor 96. A bit line bar BLB 142 in the first conductive layer contacts the conductive layer 138 through a fifth via 144, such that the bit line bar BLB 142 is connected to the fourth active area 108 through the fifth via 144 and the conductive layer 138. Another conductive layer 146, such as a metal over diffusion (MD) layer, is disposed on the fourth active area 108 and on the third active area 106 on the other side of the gate 140 of the right pass gate transistor 96. The gate 140 of the right pass gate transistor 96 is connected to the WL 162 in the first conductive layer through a sixth via 148. In some embodiments, one or more dielectric layers (not shown for clarity) are disposed on the conductive layers, such as the conductive layers 138 and 146, and on the gate, such as the gate 140. The vias, such as the fifth via 144 and the sixth via 148, are formed through the dielectric layers. The first conductive layers, such as BLB 142 and WL 162, are formed on the one or more dielectric layers, such that the conductive layers are electrically connected to the first conductive layers through the vias.

The right pull-down transistor 92 is laid out with a conductive layer 150, such as a metal over diffusion (MD) layer, disposed on the fourth active area 108 on one side of a gate 152, and a reference line 154 in the first conductive layer is connected to the conductive layer 150 through a seventh via 156. The other side of the gate 152 includes the conductive layer 146 disposed on the third active area 106 and on the fourth active area 108. The right pull-up transistor 90 is laid out with a conductive layer 158, such as a metal over diffusion (MD) layer, disposed on the third active area 106 on one side of the gate 152, and the CVDD power supply line 134 in the first conductive layer is connected to the conductive layer 158 through an eighth via 160. The other side of the gate 152 includes the conductive layer 146 disposed on the third active area 106 and on the fourth active area 108. The gate 152 of the right pull-down transistor 92 and the right pull-up transistor 90 crosses the third active area 106 and the fourth active area 108. In some embodiments, one or more dielectric layers (not shown for clarity) are disposed on the conductive layers, such as the conductive layers 150 and 158, and on the gate, such as the gate 152. The vias, such as the seventh via 156 and the eighth via 160, are formed through the dielectric layers. The first conductive layers, such as the reference line 154 and the CVDD power supply line 134, are formed on the one or more dielectric layers, such that the conductive layers are electrically connected to the first conductive layers through the vias.

The conductive layer 118 is electrically connected to the gate 152 of the right pull-down transistor 92 and the right pull-up transistor 90 and the conductive layer 146 is electrically connected to the gate 126 of the left pull-down transistor 88 and the left pull-up transistor 86.

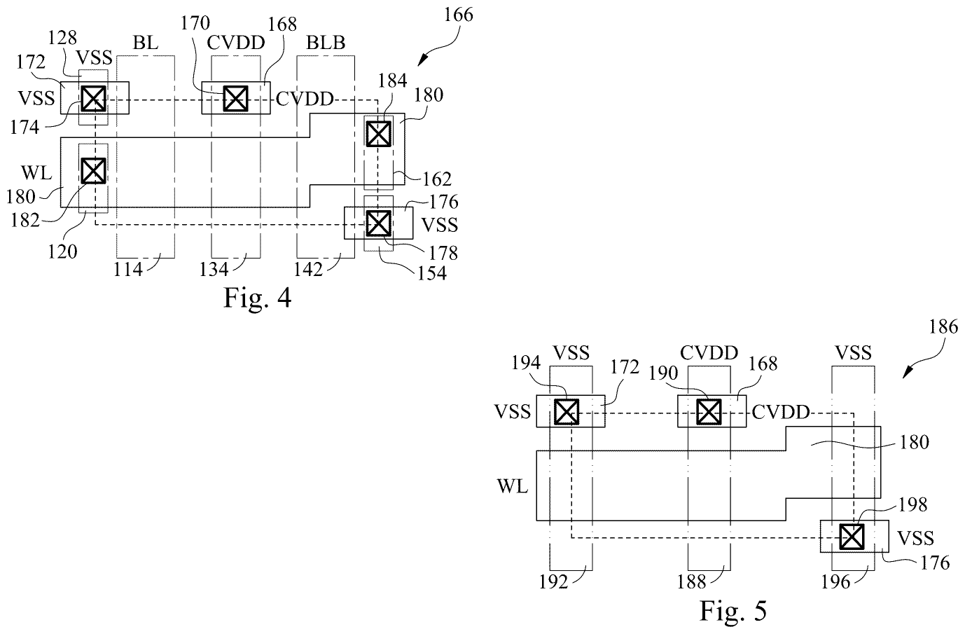

FIG. 4 is a diagram schematically illustrating a layout 166 of the SRAM cell 80 of FIG. 2, which includes a second conductive layer island 168 connected to the CVDD power supply line 134 in the first conductive layer through a ninth via 170, in accordance with some embodiments. The layout 166 includes the first conductive layer that is the first metal layer M0 and the second conductive layer that is a second metal layer M1. A footprint of the second conductive layer island 168 is situated between a footprint of the first conductive layer bit line BL 114 and a footprint of the first conductive layer bit line bar BLB 142. The second conductive layer island 168 is connected to a third conductive layer that is a third metal layer M2 form the CVDD power mesh, which increases the maximum voltage Vmax at the memory cells and improves the RSNM of the memory cells. In some embodiments, one or more dielectric layers (not shown for clarity) are disposed on the first conductive layer, such as the CVDD power supply line 134. The via, such as the ninth via 170, is formed through the one or more dielectric layers. The second conductive layer island, such as the second conductive layer island 168, is formed on the one or more dielectric layers, such that the first conductive layer is electrically connected to the second conductive layer island through the via.

The layout 166 includes the reference line 128 in the first conductive layer and the reference line 154 in the first conductive layer. The reference line 128 is connected to a reference line island 172 in the second conductive layer through a tenth via 174, and the reference line 154 is connected to a reference line island 176 in the second conductive layer through an eleventh via 178. The reference line island 172 and the reference line island 176 are connected to the third conductive layer that is the third metal layer M2 to form the VSS reference mesh. In some embodiments, one or more dielectric layers (not shown for clarity) are disposed on the first conductive layers, such as the reference lines 128 and 154. The vias, such as the tenth via 174 and the eleventh via 178, are formed through the one or more dielectric layers. The second conductive layer islands, such as the reference line islands 172 and 176, are formed on the one or more dielectric layers, such that the first conductive layers are electrically connected to the second conductive layer islands through the vias.

The layout 166 includes the WL 120 and the WL 162 in the first conductive layer. The WL 120 in the first conductive layer is connected to a WL 180 in the second conductive layer through a twelfth via 182 and the WL 162 in the first conductive layer is connected to the WL 180 in the second conductive layer through a thirteenth via 184, which connects the WLs 120 and 162. In some embodiments, one or more dielectric layers (not shown for clarity) are disposed on the first conductive layers, such as the WLs 120 and 162. The vias, such as the twelfth via 182 and the thirteenth via 184, are formed through the one or more dielectric layers. The second conductive layer, such as the WL 180, is formed on the one or more dielectric layers, such that the first conductive layers are electrically connected to the second conductive layer through the vias.

FIG. 5 is a diagram schematically illustrating a layout 186 of the SRAM cell 80 of FIG. 2, which includes the second conductive layer island 168 connected to a CVDD power supply line 188 in a third conductive layer, in accordance with some embodiments. The layout 186 includes the second conductive layer that is the second metal layer M1 and the third conductive layer that is a third metal layer M2. The second conductive layer island 168 is connected to the CVDD power supply line 188 in the third conductive layer through a fourteenth via 190 to form the CVDD power mesh, which increases the maximum voltage Vmax at the memory cells and improves the RSNM of the memory cells. In some embodiments, one or more dielectric layers (not shown for clarity) are disposed on the second conductive layer, such as the second conductive layer island 168. The via, such as the fourteenth via 190, is formed through the one or more dielectric layers. The third conductive layer, such as the CVDD power supply line 188, is formed on the one or more dielectric layers, such that the second conductive layer island is electrically connected to the third conductive layer through the via.

The layout 186 includes the reference line island 172 in the second conductive layer connected to a VSS reference line 192 in the third conductive layer through a fifteenth via 194, and the reference line island 176 in the second conductive layer connected to a VSS reference line 196 in the third conductive layer through a sixteenth via 198 to form the VSS reference mesh. A footprint of the second conductive layer island 168 is situated between a footprint of the VSS reference line 192 and the VSS reference line 196. Also, the layout 186 includes the WL 180 in the second conductive layer. In some embodiments, one or more dielectric layers (not shown for clarity) are disposed on the second conductive layer, such as the reference line islands 172 and 176 and the WL 180. The vias, such as the fifteenth via 194 and the sixteenth via 198, are formed through the one or more dielectric layers. The third conductive layer, such as the VSS reference lines 192 and 196, is formed on the one or more dielectric layers, such that the second conductive layers are electrically connected to the third conductive layers through the vias.

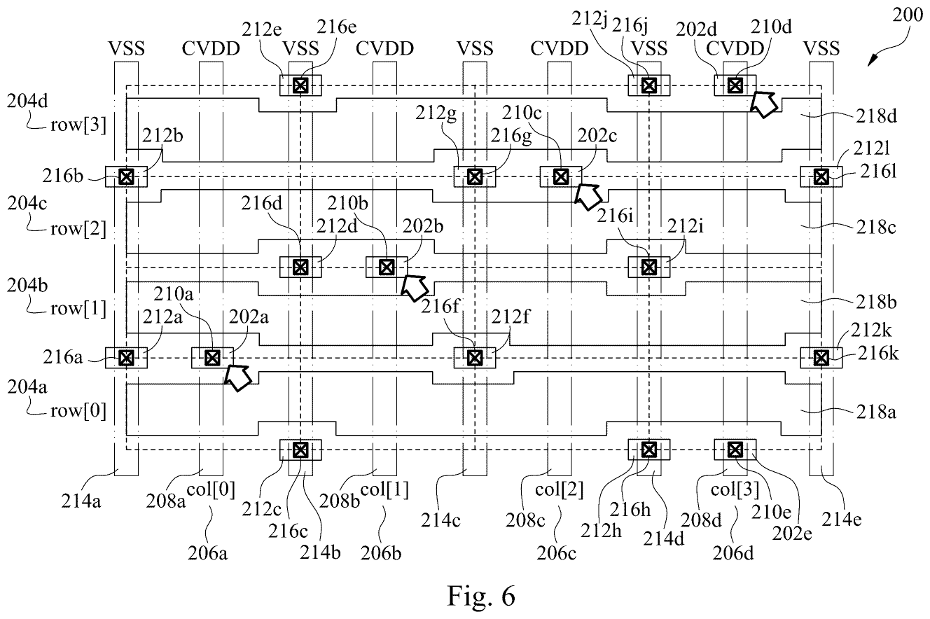

FIG. 6 is a diagram schematically illustrating a memory array 200 that includes power supply voltage islands 202a-202e in a second conductive layer, once every 4 rows in each column of the memory array 200, in accordance with some embodiments. The memory array 200 includes memory cells in rows of memory cells 204a-204d and columns of memory cells 206a-206d. In some embodiments, the second conductive layer is a second metal layer M1. In some embodiments, the memory array 200 is like the memory array 22 of FIG. 1.

The memory array 200 includes CVDD power supply lines 208a-208d in a third conductive layer. Each of the CVDD power supply lines 208a-208d in the third conductive layer is connected to at least one of the power supply voltage islands 202a-202e in the second conductive layer. The CVDD power supply line 208a is connected to the power supply voltage island 202a in row(0) 204a through a first via 210a, the CVDD power supply line 208b is connected to the power supply voltage island 202b in row(1) 204b through a second via 210b, the CVDD power supply line 208c is connected to the power supply voltage island 202c in row(2) 204c through a third via 210c, and the CVDD power supply line 208d is connected to the power supply voltage island 202d in row(3) 204d through a fourth via 210d and the CVDD power supply line 208d is connected to the power supply voltage island 202e through a fifth via 210e. In some embodiments, the third conductive layer is a third metal layer M2.

The memory array 200 includes reference voltage islands 212a-212l in the second conductive layer and reference lines 214a-214e in the third conductive layer. Each of the reference lines 214a-214e in the third conductive layer is connected to at least one of the reference voltage islands 212a-212l in the second conductive layer. The reference line 214a is connected to the reference voltage islands 212a and 212b through a sixth via 216a and a seventh via 216b, respectively. The reference line 214b is connected to the reference voltage islands 212c, 212d, and 212e through an eighth via 216c, a ninth via 216d, and a tenth via 216e, respectively. The reference line 214c is connected to the reference voltage islands 212f and 212g through an eleventh via 216f and a twelfth via 216g, respectively. The reference line 214d is connected to the reference voltage islands 212h, 212i, and 212j through a thirteenth via 216h, a fourteenth via 216i, and a fifteenth via 216j, respectively. The reference line 214e is connected to the reference voltage islands 212k and 212l through a sixteenth via 216k and a seventeenth via 216l, respectively.

The memory array 200 includes WLs 218a-218d in the second conductive layer. One of the WLs 218a-218d in each of the rows 204a-204d. The WLs 218a-218d are formed around each of the power supply voltage islands 202a-202e and around each of the reference voltage islands 212a-212l. In some embodiments, each column of memory cells 206a-206d includes a memory cell that includes a power supply voltage island in the second conductive layer, such as one of the power supply voltage islands 202a-202e, connected to a first conductive layer, such as metal layer M0, that is connected to a memory cell, and further connected to a CVDD power supply line in the third conductive layer, such as one of the CVDD power supply lines 208a-208d, once in every 2 times N rows, where N is a positive integer. In some embodiments N is equal to 2.

The memory array 200 includes WLs 218a-218d in the second conductive layer, such that increasing N reduces word line resistance and capacitance and increases the core voltage distribution network resistance. Also, the word line resistance and capacitance versus core voltage distribution network resistance can be optimized by changing N.

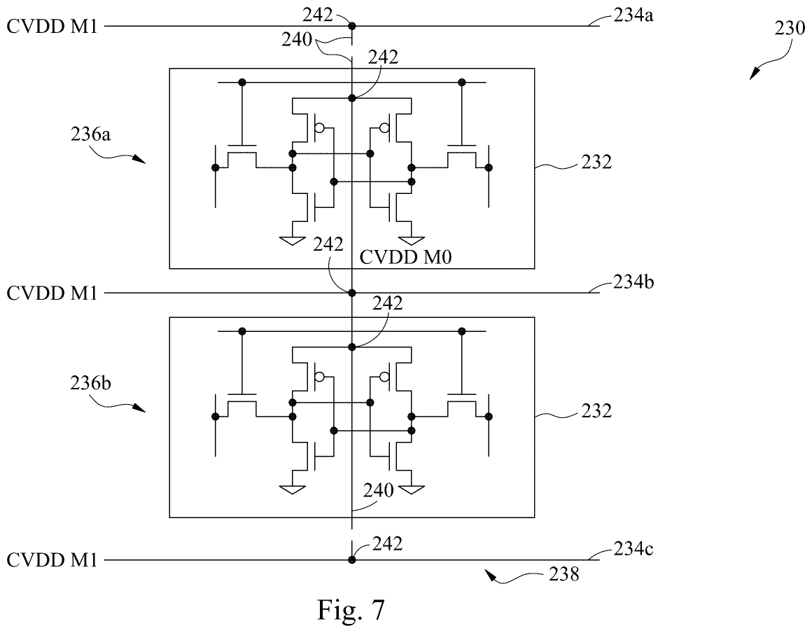

FIG. 7 is a diagram schematically illustrating a memory array 230 that includes a plurality of memory cells 232 and power supply voltage lines 234a-234c that cross the memory array 230, including between the memory cells 232, in accordance with some embodiments. The power supply voltage lines 234a-234c are core voltage distribution lines in a second conductive layer that is a second metal layer M1. The memory array 230 includes the memory cells 232 in a plurality of rows 236a and 236b and a plurality of columns, such as column 238. In some embodiments, the memory array 230 is like the memory array 22, shown in FIG. 1. In some embodiments, the memory cells 232 are like the memory cells 24, shown in FIG. 1.

The memory cells 232 are like the memory cell 80 of FIG. 2 and the memory cell layouts 100, 166, and 186 of FIGS. 3-5, respectively. Each of the memory cells 232 includes a conductive layer over an active area. A CVDD voltage line 240 in a first conductive layer that is a first metal layer M0 is connected by vias 242 to the power supply voltage lines 234a-234c and to the conductive layers of the memory cells 232. The memory cells 232 receive a CVDD core voltage from the power supply voltage lines 234a-234c through the CVDD voltage line 240 that is connected to the conductive layers of the memory cells 232. The resistance through the CVDD voltage line 240 to the memory cells 232 from the power supply voltage lines 234a-234c is reduced due to having one or more extra power supply voltage lines 234a-234c, which increases the maximum voltage Vmax at the memory cells 232 and improves the RSNM of the memory cells 232. In some embodiments, the power supply voltage line 234a is situated at the top of the memory array 230, the power supply voltage line 234c is situated at the bottom of the memory array 230, and the power supply voltage line 234b is situated in the middle of the memory array 230.

In some embodiments, the power supply voltage lines 234a-234c, also referred to as core voltage distribution lines, are situated between each row of memory cells 232 in the memory array 230 and connected by vias 242 to the CVDD voltage line 240. In some embodiments, the power supply voltage lines 234a-234c are situated between every other row of memory cells 232 in the memory array 230 and connected by vias 242 to the CVDD voltage line 240.

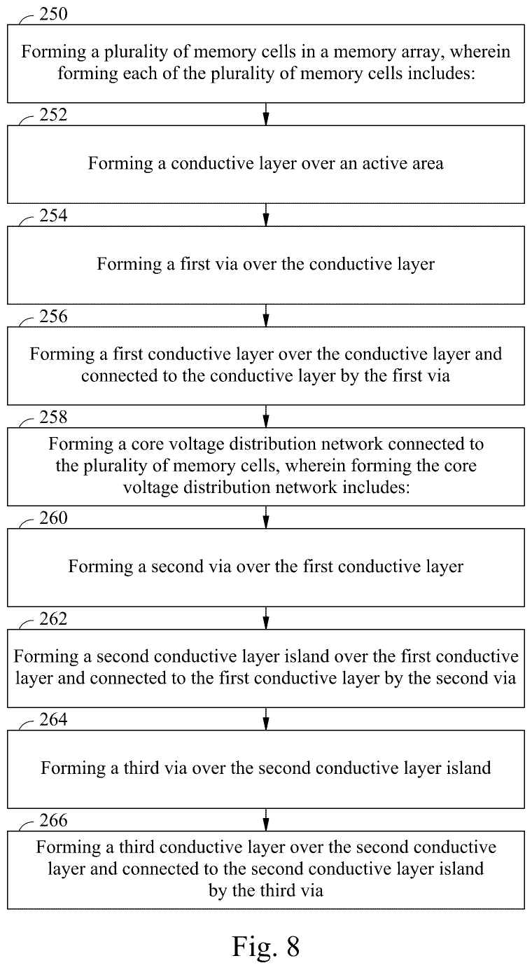

FIG. 8 is a diagram schematically illustrating a method of manufacturing a memory device, in accordance with some embodiments. At step 250, the method includes forming a plurality of memory cells in a memory array, wherein forming each of the plurality of memory cells includes: at step 252, forming a conductive layer over an active area; at step 254, forming a first via over the conductive layer; and at step 256, forming a first conductive layer over the conductive layer and connected to the conductive layer by the first via.

The method continues, at step 258, with forming a core voltage distribution network connected to the plurality of memory cells, wherein forming the core voltage distribution network includes: at step 260, forming a second via over the first conductive layer; at step 262, forming a second conductive layer island over the first conductive layer and connected to the first conductive layer by the second via; at step 264, forming a third via over the second conductive layer island; and at step 266, forming a third conductive layer over the second conductive layer and connected to the second conductive layer island by the third via.

In some embodiments, forming each of the plurality of memory cells includes forming the core voltage distribution network in each of the plurality of memory cells including: forming the second via over the first conductive layer; forming the second conductive layer island over the first conductive layer and connected to the first conductive layer by the second via; forming the third via over the second conductive layer island; and forming the third conductive layer over the second conductive layer and connected to the second conductive layer island by the third via.

In some embodiments, forming a plurality of memory cells in a memory array includes forming the plurality of memory cells in rows and columns and forming a memory cell in each column that includes the second conductive layer island connected to the first conductive layer by the second via and the third conductive layer connected to the second conductive layer island by the third via, once in every 2 times N rows, where N is a positive integer.

In some embodiments, forming the second conductive layer island includes forming a footprint of the second conductive layer island in a memory cell situated between a footprint of a first conductive layer bit line BL in the memory cell and a footprint of a first conductive layer bit line bar BLB in the memory cell.

In some embodiments, forming the second conductive layer island includes forming a footprint of the second conductive layer island in a memory cell situated between a footprint of a first VSS line in the memory cell and a second VSS line in the memory cell.

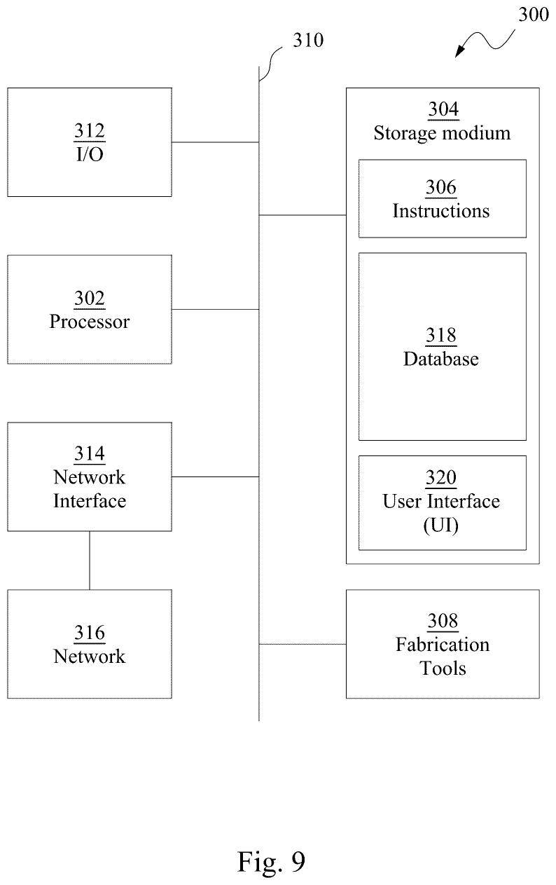

FIG. 9 is a block diagram schematically illustrating an example of a computer system 300 configured to provide the devices, including electronic devices and semiconductor devices, and methods of the current disclosure, in accordance with some embodiments. Some or all the design, layout, and manufacture of the semiconductor devices, also referred to as semiconductor circuits, can be performed by or with the aid of the computer system 300. Also, some or all the design, layout, and manufacture of the devices including electronic devices can be performed by or with the aid of the computer system 300. In some embodiments, the computer system 300 includes an electronic design automation (EDA) system. In some embodiments, the semiconductor devices are ICs.

In some embodiments, the system 300 is a general-purpose computing device including a processor 302 and a non-transitory, computer-readable storage medium 304. The computer-readable storage medium 304 may be encoded with, e.g., store, computer program code such as executable instructions 306. Execution of the instructions 306 by the processor 302 provides (at least in part) a design tool that implements a portion or all the functions of the system 300, such as pre-layout simulations, post-layout simulations, routing, rerouting, and final layout for manufacturing. Further, fabrication tools 308 are included to further layout and physically implement the design and manufacture of the semiconductor devices. In some embodiments, execution of the instructions 306 by the processor 302 provides (at least in part) a design tool that implements a portion or all the functions of the system 300. In some embodiments, the system 300 includes a commercial router. In some embodiments, the system 300 includes an automatic place and route (APR) system.

The processor 302 is electrically coupled to the computer-readable storage medium 304 by a bus 310 and to an I/O interface 312 by the bus 310. A network interface 314 is also electrically connected to the processor 302 by the bus 310. The network interface 314 is connected to a network 316, so that the processor 302 and the computer-readable storage medium 304 can connect to external elements using the network 316. The processor 302 is configured to execute the computer program code or instructions 306 encoded in the computer-readable storage medium 304 to cause the system 300 to perform a portion or all the functions of the system 300, such as providing the semiconductor devices and methods of the current disclosure and other functions of the system 300. In some embodiments, the processor 302 is a central processing unit (CPU), a multi-processor, a distributed processing system, an application specific integrated circuit (ASIC), and/or a suitable processing unit.

In some embodiments, the computer-readable storage medium 304 is an electronic, magnetic, optical, electromagnetic, infrared, and/or semiconductor system or apparatus or device. For example, the computer-readable storage medium 304 can include a semiconductor or solid-state memory, a magnetic tape, a removable computer diskette, a random-access memory (RAM), a read-only memory (ROM), a rigid magnetic disk, and/or an optical disk. In some embodiments using optical disks, the computer-readable storage medium 304 can include a compact disk read only memory (CD-ROM), a compact disk read/write memory (CD-R/W), and/or a digital video disc (DVD).

In some embodiments, the computer-readable storage medium 304 stores computer program code or instructions 306 configured to cause the system 300 to perform a portion or all the functions of the system 300. In some embodiments, the computer-readable storage medium 304 also stores information which facilitates performing a portion or all the functions of the system 300. In some embodiments, the computer-readable storage medium 304 stores a database 318 that includes one or more of component libraries, digital circuit cell libraries, and databases.

The system 300 includes the I/O interface 312, which is coupled to external circuitry. In some embodiments, the I/O interface 312 includes a keyboard, keypad, mouse, trackball, trackpad, touchscreen, and/or cursor direction keys for communicating information and commands to the processor 302.

The network interface 314 is coupled to the processor 302 and allows the system 300 to communicate with the network 316, to which one or more other computer systems are connected. The network interface 314 can include: wireless network interfaces such as BLUETOOTH, WIFI, WIMAX, GPRS, or WCDMA; or wired network interfaces such as ETHERNET, USB, or IEEE-1364. In some embodiments, a portion or all the functions of the system 300 can be performed in two or more systems that are like system 300.

The system 300 is configured to receive information through the I/O interface 312. The information received through the I/O interface 312 includes one or more of instructions, data, design rules, libraries of components and cells, and/or other parameters for processing by the processor 302. The information is transferred to the processor 302 by the bus 310. Also, the system 300 is configured to receive information related to a user interface (UI) through the I/O interface 312. This UI information can be stored in the computer-readable storage medium 304 as a UI 320.

In some embodiments, a portion or all the functions of the system 300 are implemented via a standalone software application for execution by a processor. In some embodiments, a portion or all the functions of the system 300 are implemented in a software application that is a part of an additional software application. In some embodiments, a portion or all the functions of the system 300 are implemented as a plug-in to a software application. In some embodiments, at least one of the functions of the system 300 is implemented as a software application that is a portion of an EDA tool. In some embodiments, a portion or all the functions of the system 300 are implemented as a software application that is used by the system 300. In some embodiments, a layout diagram is generated using a tool such as VIRTUOSO available from CADENCE DESIGN SYSTEMS, Inc., or another suitable layout generating tool.

In some embodiments, the routing, layouts, and other processes are realized as functions of a program stored in a non-transitory computer readable recording medium. Examples of a non-transitory computer readable recording medium include, but are not limited to, external/removable and/or internal/built-in storage or memory units, e.g., one or more optical disks such as a digital video disc or a digital versatile disc (DVD), a magnetic disk such as a hard disk, a semiconductor memory such as a ROM and a RAM, and a memory card, and the like.

As noted above, embodiments of the system 300 include fabrication tools 308 for implementing the manufacturing processes of the system 300. For example, based on the final layout, photolithographic masks may be generated, which are used to fabricate the semiconductor device by the fabrication tools 308.

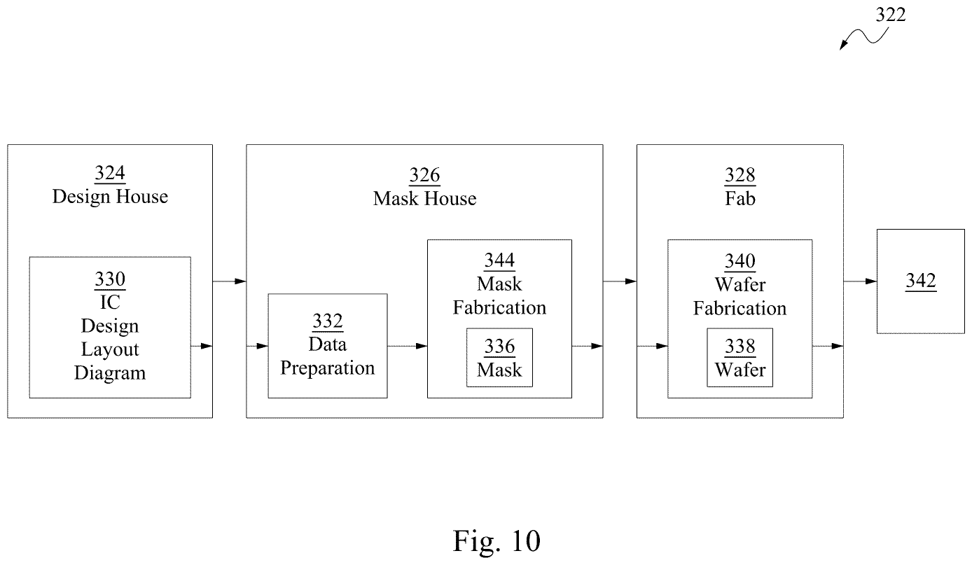

Further aspects of device fabrication are disclosed in conjunction with FIG. 10, which is a block diagram of a semiconductor device manufacturing system 322 and a semiconductor device manufacturing flow associated therewith, in accordance with some embodiments. In some embodiments, based on a layout diagram, one or more semiconductor masks and/or at least one component in a layer of a semiconductor device is fabricated using the manufacturing system 322.

In FIG. 10, the semiconductor device manufacturing system 322 includes entities, such as a design house 324, a mask house 326, and a semiconductor device manufacturer/fabricator (“Fab”) 328, that interact with one another in the design, development, and manufacturing cycles and/or services related to manufacturing a semiconductor device, such as the semiconductor devices described herein. The entities in the system 322 are connected by a communications network. In some embodiments, the communications network is a single network. In some embodiments, the communications network is a variety of different networks, such as an intranet and the internet. The communications network includes wired and/or wireless communication channels. Each entity interacts with one or more of the other entities and provides services to and/or receives services from one or more of the other entities. In some embodiments, two or more of the design house 324, the mask house 326, and the semiconductor device fab 328 are owned by a single larger company. In some embodiments, two or more of the design house 324, the mask house 326, and the semiconductor device fab 328 coexist in a common facility and use common resources.

The design house (or design team) 324 generates a semiconductor device design layout diagram 330. The semiconductor device design layout diagram 330 includes various geometrical patterns, or semiconductor device layout diagrams designed for a semiconductor device. The geometrical patterns correspond to patterns of metal, oxide, or semiconductor layers that make up the various components of the semiconductor structures to be fabricated. The various layers combine to form various semiconductor device features. For example, a portion of the semiconductor device design layout diagram 330 includes various semiconductor device features, such as diagonal vias, active areas or regions, gate electrodes, sources, drains, metal lines, local vias, and openings for bond pads, to be formed in a semiconductor substrate (such as a silicon wafer) and in various material layers disposed on the semiconductor substrate. The design house 324 implements a design procedure to form a semiconductor device design layout diagram 330. The semiconductor device design layout diagram 330 is presented in one or more data files having information of the geometrical patterns. For example, semiconductor device design layout diagram 330 can be expressed in a GDSII file format or DFII file format. In some embodiments, the design procedure includes one or more of analog circuit design, digital circuit design, logic circuit design, standard cell circuit design, power distribution network (PDN) design including power via design, supply voltage track design, reference voltage track design, place and route routines, and physical layout designs.

The mask house 326 includes data preparation 332 and mask fabrication 334. The mask house 326 uses the semiconductor device design layout diagram 330 to manufacture one or more masks 336 to be used for fabricating the various layers of the semiconductor device or semiconductor structure. The mask house 326 performs mask data preparation 332, where the semiconductor device design layout diagram 330 is translated into a representative data file (RDF). The mask data preparation 332 provides the RDF to the mask fabrication 334. The mask fabrication 334 includes a mask writer that converts the RDF to an image on a substrate, such as a mask (reticle) 336 or a semiconductor wafer 338. The design layout diagram 330 is manipulated by the mask data preparation 332 to comply with characteristics of the mask writer and/or criteria of the semiconductor device fab 328. In FIG. 10, the mask data preparation 332 and the mask fabrication 334 are illustrated as separate elements. In some embodiments, the mask data preparation 332 and the mask fabrication 334 can be collectively referred to as mask data preparation.

In some embodiments, the mask data preparation 332 includes an optical proximity correction (OPC) which uses lithography enhancement techniques to compensate for image errors, such as those that can arise from diffraction, interference, other process effects and the like. The OPC adjusts the semiconductor device design layout diagram 330. In some embodiments, the mask data preparation 332 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 332 includes a mask rule checker (MRC) that checks the semiconductor device design layout diagram 330 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the semiconductor device design layout diagram 330 to compensate for limitations during the mask fabrication 334, which may undo part of the modifications performed by OPC to meet mask creation rules.

In some embodiments, the mask data preparation 332 includes lithography process checking (LPC) that simulates processing that will be implemented by the semiconductor device fab 328. LPC simulates this processing based on the semiconductor device design layout diagram 330 to create a simulated manufactured device. The processing parameters in LPC simulation can include parameters associated with various processes of the semiconductor device manufacturing cycle, parameters associated with tools used for manufacturing the semiconductor device, and/or other aspects of the manufacturing process. LPC considers various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are to be repeated to further refine the semiconductor device design layout diagram 330.

The above description of mask data preparation 332 has been simplified for the purposes of clarity. In some embodiments, data preparation 332 includes additional features such as a logic operation (LOP) to modify the semiconductor device design layout diagram 330 according to manufacturing rules. Additionally, the processes applied to the semiconductor device design layout diagram 330 during data preparation 332 may be executed in a variety of different orders.

After the mask data preparation 332 and during the mask fabrication 334, a mask 336 or a group of masks 336 are fabricated based on the modified semiconductor device design layout diagram 330. In some embodiments, the mask fabrication 334 includes performing one or more lithographic exposures based on the semiconductor device design layout diagram 330. In some embodiments, an electron-beam (e-beam) or a mechanism of multiple e-beams is used to form a pattern on a mask (photomask or reticle) 336 based on the modified semiconductor device design layout diagram 330. The mask 336 can be formed in various technologies. In some embodiments, the mask 336 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region, and transmits through the transparent regions. In one example, a binary mask version of the mask 336 includes a transparent substrate (e.g., fused quartz) and an opaque material (e.g., chromium) coated in the opaque regions of the binary mask. In another example, the mask 336 is formed using a phase shift technology. In a phase shift mask (PSM) version of the mask 336, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 334 is used in a variety of processes. For example, such a mask(s) is used in an ion implantation process to form various doped regions in the semiconductor wafer 338, in an etching process to form various etching regions in the semiconductor wafer 338, and/or in other suitable processes.

The semiconductor device fab 328 includes wafer fabrication 340. The semiconductor device fab 328 is a semiconductor device fabrication business that includes one or more manufacturing facilities for the fabrication of a variety of different semiconductor device products. In some embodiments, the semiconductor device fab 328 is a semiconductor foundry. For example, there may be a manufacturing facility for the front end of line (FEOL) fabrication of a plurality of semiconductor device products, while a second manufacturing facility may provide the BEOL fabrication for the interconnection and packaging of the semiconductor device products, and a third manufacturing facility may provide other services for the foundry business.

The semiconductor device fab 328 uses the mask(s) 336 fabricated by the mask house 326 to fabricate the semiconductor structures or semiconductor devices 342 of the current disclosure. Thus, the semiconductor device fab 328 at least indirectly uses the semiconductor device design layout diagram 330 to fabricate the semiconductor structures or semiconductor devices 342 of the current disclosure. Also, the semiconductor wafer 338 includes a silicon substrate or other proper substrate having material layers formed thereon, and the semiconductor wafer 338 further includes one or more of various doped regions, dielectric features, multilevel interconnects, and the like (formed at subsequent manufacturing steps). In some embodiments, the semiconductor wafer 338 is fabricated by the semiconductor device fab 328 using the mask(s) 336 to form the semiconductor structures or semiconductor devices 342 of the current disclosure. In some embodiments, the semiconductor device fabrication includes performing one or more lithographic exposures based at least indirectly on the semiconductor device design layout diagram 330.

Disclosed embodiments thus provide a memory device that includes a power mesh using second conductive layer islands, such as in an M1 layer, connected by a via to a first conductive layer, such as an M0 layer, that is connected to memory cells in the memory device. A third conductive layer, such as an M2 layer, is connected by another via to the second conductive layer islands to form the power mesh, which increases the maximum voltage Vmax at the memory cells and improves the RSNM of the memory cells.

In some embodiments, the memory device includes a memory array that includes memory cells in rows and columns. Each column of memory cells includes power mesh memory cells that include a second conductive layer island connected by a via to a first conductive layer, and a third conductive layer connected by another via to the second conductive layer island. In some embodiments, each column of the memory array includes a power mesh memory cell once every 2 times N rows, where N is a positive integer. In some embodiments, the memory array includes word lines in the second conductive layer, such that increasing N decreases the number of second conductive layer islands, which increases the power mesh resistance, and increases the word line area, which reduces word line resistance and capacitance.

Disclosed embodiments further include a memory device that includes a memory array and a core voltage distribution network. The memory array includes memory cells situated in rows and columns, where each of the memory cells includes a conductive layer over an active area and a first conductive layer connected to the conductive layer. The core voltage distribution network includes a second conductive layer that includes at least one core voltage distribution line situated between rows of memory cells in the memory array and connected to the first conductive layer. The core voltage distribution network increases the maximum voltage Vmax at the memory cells and improves the RSNM of the memory cells.

Disclosed embodiments further include a method of manufacturing a memory device. The method includes forming a plurality of memory cells in a memory array and forming a core voltage distribution network connected to the plurality of memory cells. Forming each of the plurality of memory cells includes forming a conductive layer over an active area, forming a first via over the conductive layer, and forming a first conductive layer over the conductive layer and connected to the conductive layer by the first via. Forming the core voltage distribution network includes forming a second via over the first conductive layer, forming a second conductive layer island over the first conductive layer and connected to the first conductive layer by the second via, forming a third via over the second conductive layer island, and forming a third conductive layer over the second conductive layer and connected to the second conductive layer island by the third via.

In accordance with some embodiments, a memory device includes a memory array having a plurality of memory cells and a core voltage distribution network connected to the plurality of memory cells. Each of the plurality of memory cells includes a conductive layer over an active area and a first conductive layer connected by a first via to the conductive layer over the active area. The core voltage distribution network includes a second conductive layer that includes a second conductive layer island connected by a second via to the first conductive layer, and a third conductive layer connected by a third via to the second conductive layer island.

In accordance with further embodiments, a memory device includes a memory array having a plurality of memory cells situated in rows and columns. Each of the plurality of memory cells includes a conductive layer over an active area, and a first conductive layer connected by a first via to the conductive layer. Each column of the memory array includes a memory cell that includes a second conductive layer island connected by a second via to the first conductive layer and a third conductive layer connected by a third via to the second conductive layer island.

In accordance with still further disclosed aspects, a memory device includes a memory array having a plurality of memory cells situated in a plurality of rows of memory cells and a plurality of columns of memory cells, and a core voltage distribution network. Each of the plurality of memory cells includes a conductive layer over an active area and a first conductive layer connected by a first via to the conductive layer, wherein the first conductive layer is configured to receive a core voltage. The core voltage distribution network includes a second conductive layer that includes at least one core voltage distribution line situated between rows of memory cells of the plurality of rows of memory cells in the memory array and connected by at least one second via to the first conductive layer.

In accordance with still further disclosed aspects, a method of manufacturing a memory device includes forming a plurality of memory cells in a memory array and forming a core voltage distribution network connected to the plurality of memory cells. Forming each of the plurality of memory cells includes forming a conductive layer over an active area; forming a first via over the conductive layer; and forming a first conductive layer over the conductive layer and connected to the conductive layer by the first via. Further, forming the core voltage distribution network includes forming a second via over the first conductive layer; forming a second conductive layer island over the first conductive layer and connected to the first conductive layer by the second via; forming a third via over the second conductive layer island; and forming a third conductive layer over the second conductive layer and connected to the second conductive layer island by the third via.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a memory array having a plurality of memory cells, wherein each of the plurality of memory cells includes:
a conductive layer over an active area; and
a first conductive layer connected by a first via to the conductive layer over the active area; and
a core voltage distribution network connected to the plurality of memory cells, wherein the core voltage distribution network includes:
a second conductive layer that includes a second conductive layer island connected by a second via to the first conductive layer; and
a third conductive layer connected by a third via to the second conductive layer island.

2. The memory device of claim 1, wherein each of the plurality of memory cells includes:
the second conductive layer island connected by the second via to the first conductive layer; and
the third conductive layer connected by the third via to the second conductive layer island.

3. The memory device of claim 1, wherein the memory array includes the plurality of memory cells in rows and columns and each column includes a memory cell that includes the second conductive layer island connected by the second via to the first conductive layer and the third conductive layer connected by the third via to the second conductive layer island, once in every 2 times N rows, where N is a positive integer.

4. The memory device of claim 3, wherein the memory array includes word lines in the second conductive layer, such that increasing N reduces word line resistance and capacitance and increases a core voltage distribution network resistance.

5. The memory device of claim 3, wherein the memory array includes word lines in the second conductive layer, such that word line resistance and capacitance versus core voltage distribution network resistance can be optimized by changing N.

6. The memory device of claim 1, wherein the memory array includes the plurality of memory cells in rows and columns and each column includes a memory cell once in every 4 rows that includes the second conductive layer island connected by the second via to the first conductive layer and the third conductive layer connected by the third via to the second conductive layer island.

7. The memory device of claim 1, wherein a footprint of the second conductive layer island in a memory cell is situated between a footprint of a first conductive layer bit line in the memory cell and a footprint of a first conductive layer bit line bar in the memory cell.

8. The memory device of claim 1, wherein a footprint of the second conductive layer island in a memory cell is situated between a footprint of a first VSS line in the memory cell and a second VSS line in the memory cell.

9. The memory device of claim 1, wherein each of the plurality of memory cells is a static random-access memory cell.

10. The memory device of claim 1, wherein each of the plurality of memory cells is a 6 transistor static random-access memory cell.

11. A memory device, comprising:
a memory array having a plurality of memory cells situated in rows and columns, each of the plurality of memory cells including:
a conductive layer over an active area; and
a first conductive layer connected by a first via to the conductive layer,
wherein each column of the memory array includes a memory cell that includes a second conductive layer island connected by a second via to the first conductive layer and a third conductive layer connected by a third via to the second conductive layer island.

12. The memory device of claim 11, wherein each column includes the memory cell once in every 2 times N rows of the column, where N is a positive integer.

13. The memory device of claim 12, wherein the memory array includes word lines in the second conductive layer, such that increasing N reduces word line resistance and capacitance and increases core voltage distribution network resistance.

14. The memory device of claim 12, wherein N is 2.

15. The memory device of claim 11, wherein a footprint of the second conductive layer island in the memory cell is situated between a footprint of a first conductive layer bit line in the memory cell and a footprint of a first conductive layer bit line bar in the memory cell.

16. The memory device of claim 11, wherein a footprint of the second conductive layer island in the memory cell is situated between a footprint of a first VSS line in the memory cell and a second VSS line in the memory cell.

17. A method of manufacturing a memory device, the method comprising:
forming a plurality of memory cells in a memory array, wherein forming each of the plurality of memory cells includes:
forming a conductive layer over an active area;
forming a first via over the conductive layer; and
forming a first conductive layer over the conductive layer and connected to the conductive layer by the first via; and
forming a core voltage distribution network connected to the plurality of memory cells, wherein forming the core voltage distribution network includes:
forming a second via over the first conductive layer;
forming a second conductive layer island over the first conductive layer and connected to the first conductive layer by the second via;
forming a third via over the second conductive layer island; and
forming a third conductive layer over the second conductive layer and connected to the second conductive layer island by the third via.

18. The method of claim 17, wherein forming each of the plurality of memory cells includes forming the core voltage distribution network in each of the plurality of memory cells including:
forming the second via over the first conductive layer;
forming the second conductive layer island over the first conductive layer and connected to the first conductive layer by the second via;
forming the third via over the second conductive layer island; and
forming the third conductive layer over the second conductive layer and connected to the second conductive layer island by the third via.

19. The method of claim 17, wherein forming a plurality of memory cells in a memory array includes forming the plurality of memory cells in rows and columns and forming a memory cell in each column that includes the second conductive layer island connected to the first conductive layer by the second via and the third conductive layer connected to the second conductive layer island by the third via, once in every 2 times N rows, where N is a positive integer.

20. The method of claim 17, wherein forming the second conductive layer island includes forming a footprint of the second conductive layer island in a first memory cell situated between a footprint of a first conductive layer bit line in the memory cell and a footprint of a first conductive layer bit line bar in the memory cell or forming the footprint of the second conductive layer island in a second memory cell situated between a footprint of a first VSS line in the memory cell and a second VSS line in the memory cell.
